(19) United States
(12) Patent Application Publication
(10) Pub. No.: US 2024/0429019 A1
(43) Pub. Date: Dec. 26, 2024

(54) MAGNETIC ROTATION DEVICE FOR HIGH VACUUM APPLICATIONS SUCH AS ION AND ISOTOPE PRODUCTION

(71) Applicant: SHINE Technologies, LLC, Janesville, WI (US)

(72) Inventor: Daniel Martin, Janesville, WI (US)

(73) Assignee: SHINE Technologies, LLC, Janesville, WI (US)

(21) Appl. No.: 18/294,051

(22) PCT Filed: Aug. 13, 2021
(86) PCT No.: PCT/US2021/045855

§ 371 Date: Jan. 31, 2024

(51) Int. Cl. H01J 37/20; H01J 37/08

(52) U.S. Cl. CPC H01J 37/20; H01J 37/08; H01J 2237/028; H01J 2237/20214; H01J 2237/20257

(57) ABSTRACT

An apparatus includes a wall defining a boundary of an evacuated space and having a first side interior to the evacuated space and a second side exterior to the evacuated space, a first plate positioned on a first side of the wall and including a first magnet, a second plate positioned on a second side of the wall and including a second magnet, and a motor mechanically coupled to the second plate and configured to drive rotation of the second plate. The second magnet exerts an attractive force on the first magnet that causes rotation of the first plate in response to the rotation of the second plate.

### FIELD

The present disclosure relates, in some respects, to the field of ion and/or isotope production, for example production of heavy metal ions or isotopes such as those used in health care applications. In other respects, the present disclosure relates to actuators and other devices suitable for use with high vacuum enclosures, such as those that may be used in ion and/or isotope production.

### SUMMARY

One implementation of the present disclosure is an apparatus. The apparatus includes a wall defining a boundary of an evacuated space and having a first side interior to the evacuated space and a second side exterior to the evacuated space, a first plate positioned on a first side of the wall and including a first magnet, a second plate positioned on a second side of the wall and including a second magnet, and a motor mechanically coupled to the second plate and configured to drive rotation of the second plate. The second magnet exerts an attractive force on the first magnet that causes rotation of the first plate in response to the rotation of the second plate.

In some embodiments, the attractive force enables heat transfer from the first plate to the second plate by drawing the first plate into thermal contact with the wall and the second plate into thermal contact with the wall. The apparatus may include a cooling coil in thermal contact with the second plate.

In some embodiments, the apparatus includes an axle coupled to the wall and having a first end on the first side of the wall and a second end on the second side of the wall. The first plate rides on the first end of the axle and the second plate rides on the second end of the axle. The attractive force can hold the second plate and/or the first plate on the axle. The apparatus may also include an o-ring positioned around the axle at the wall. The axle and the o-ring may be stationary relative to the wall during the rotation of the first plate and the second plate.

The first plate and the second plate may have a same shape, for example a circular shape. In some embodiments, the first plate includes a plurality of additional first magnets and the second plate also includes a plurality of additional second magnets. The first magnet and the plurality of additional first magnets are spaced apart from each other and positioned a distance away from an axis of the rotation of the first plate, and the second magnet and the plurality of additional second magnets are spaced apart from each other and positioned the same distance away from an axis of the rotation of the second plate.

In some embodiments, the first plate slides along the first side of the wall during the rotation of first plate and the second plate slides along the second side of the wall during the rotation of the second plate. A fluoropolymer dry lube may be positioned between the first plate and the first side of the wall to reduce friction therebetween.

In some embodiments, a target is mounted on the first plate. The target may be configured to trap particles from an ion beam incident thereon. The rotation of the first plate may change an area of the target exposed to the ion beam. The apparatus may also include an ion beam generator configured to generate the ion beam inside the evacuated space and direct the ion beam toward the target. The evacuated space may have a pressure less than 10 mPa, for example. The apparatus may be an ion production system.

Another implementation of the present disclosure is a method. The method includes providing an ion beam incident on a target in a vacuum chamber and rotating the target by driving rotation of an exterior plate outside the vacuum chamber, the exterior plate comprising an exterior magnet and transferring the rotation of the exterior plate to an interior plate inside the vacuum chamber via an attractive force between the exterior magnet and an interior magnet of the interior plate. The target is mounted on the interior plate.

In some embodiments, the method also includes transferring heat from the target to the exterior plate via the interior plate and a wall of the vacuum chamber. The method may also include operating a refrigeration cycle that cools the exterior plate.

In some embodiments, the method also includes driving the rotation of the exterior plate comprises operating a stepper motor coupled to the exterior plate. Rotating the target may increases an area of the target exposed to the ion beam due to misalignment of the ion beam relative to an axis of rotation of the target.

### BRIEF DESCRIPTION OF THE FIGURES

The disclosure will become more fully understood from the following detailed description taken in conjunction with the accompanying figures, where like reference numerals refer to like elements, in which:

FIG. 1 is a block diagram of an ion production system, according to some embodiments.

FIG. 2 is a block diagram of an ion production system having a magnetic rotation device, according to some embodiments.

FIG. 3 is a first isometric view of the magnetic rotation device, according to some embodiments.

FIG. 4 is a second isometric view of the magnetic rotation device, according to some embodiments.

FIG. 5 is a cross-sectional side view of the magnetic rotation device, according to some embodiments.

FIG. 6 is a front view of the magnetic rotation device, according to some embodiments.

### DETAILED DESCRIPTION

Before turning to the figures, which illustrate certain embodiments in detail, it should be understood that the present disclosure is not limited to the details or methodology set forth in the description or illustrated in the figures. It should also be understood that the terminology used herein is for the purpose of description only and should not be regarded as limiting.

Referring generally to the figures, systems and methods relating to a magnetic rotation device are shown, for example for use with an ion production system. Ion or isotope production may be performed in high vacuum (e.g., pressure less than 10 mPa) in order to avoid contamination between the particles of interest for production and air or other contaminants. As such, a vacuum chamber (sealed enclosure, hermetic box, etc.) can be provided to contain various components of the ion production system. However, in some scenarios, it may be preferable to have certain components outside of the vacuum chamber, for example to reduce contamination, ease maintenance and assembly, facilitate use, reduce size requirements for the vacuum chamber, etc.

In this regard, the present application includes a determination that it would be desirable to provide a device that can both provide for heat transfer out of (or into) a vacuum chamber while also transferring mechanical action from outside the vacuum chamber into the vacuum chamber without comprising a hermetic seal of the vacuum chamber. In the primary example herein, a magnetic rotation device is provided to rotate a target for an ion beam in an ion production system while also transferring heat away from the target. Other applications and uses of the magnetic rotation device described herein are also within the scope of the present disclosure. As described below, an electric motor driving the rotation can be positioned outside the vacuum chamber, as can cooling coils, refrigeration cycle equipment, etc. that may be included to facilitate heat transfer.

The systems and methods described herein thereby provide various advantages such as ease of maintenance, control, assembly/disassembly, improved sealing of the vacuum chamber, etc. while also achieving technical goals of rotating a component within the vacuum chamber and providing heat transfer across a wall of the vacuum chamber. In the context of an ion production system as described below, operating the magnetic rotation device can provide for collection of higher amounts of ions and/or isotopes, longer continuous operation of a production system, and heat management of a target, thereby improving the efficiency of an ion and/or isotope production system.

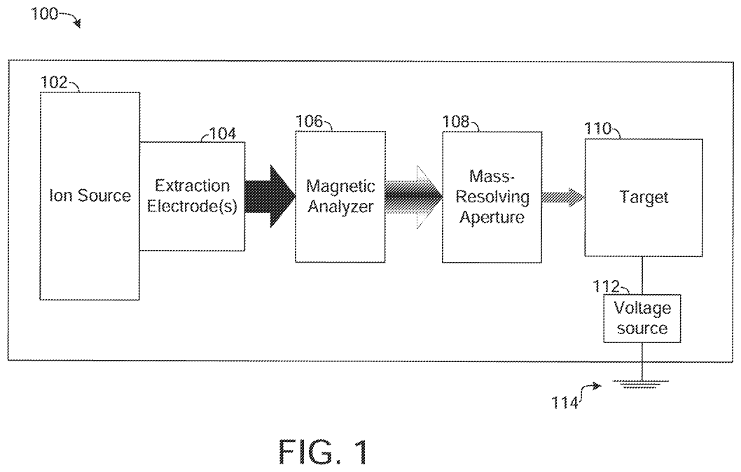

Referring now to FIG. 1, a block diagram of an ion production system 100 is shown, according to some embodiments. The ion production system 100 includes an ion source 102, extraction electrode(s) 104, a magnetic analyzer 106, a mass-resolving aperture 108, a target 110, and a voltage source 112 connected to ground 114 and to the target 110. The ion source 102, the extraction electrode(s) 104, the magnetic analyzer 106, the mass-resolving aperture 108, and the target 110 are arranged sequentially such that ions are generated at the ion source 102 and sequentially pass the extraction electrode(s) 104, magnetic analyzer 106, and mass-resolving aperture 108 before reaching the target 110. As detailed below, the ion production system 100 is configured to provide efficient collection of desired ions at the target 110 as a constituted, neutral material which can be removed, stored, transported, etc., and eventually used for some application, for example a healthcare application.

The ion source 102 is configured to produce ions. For example, the ion source 102 may be configured as a Bernas or Freeman ion source, which includes a filament operable to emit electrons which ionize a gas provided into the ion source 102, for example a heavy metal gas such as a ytterbium vapor. Other metals (Lu, Tc, etc. may also be used). Interactions between the electrons and the gas ionize the gas to produce ions. In some embodiments, the ion source 102 produces positive ions (i.e., “cations,” ions having a positive polarity). In other embodiments, the ion source produces negative ions (i.e., “anions,” ions having a negative polarity). The ion source 102 includes an outlet slit or aperture so that the ions can be extracted from the ion source 102. In some embodiments, the ion source 102 includes auxiliary heaters to protect elements of the ion source 102 and to improve uniformity of the ions for extraction from the ion source 102, for example as described in detail in U.S. Provisional Patent Application No. 63/122,699, filed Dec. 8, 2020, the entire disclosure of which is incorporated by reference herein.

The extraction electrode(s) 104 includes one or more electrodes that are configured and operated to provide an electric field that extracts the ions from the ion source 102. Because the ions have an electric charge of a first polarity (positive or negative in different embodiments), a voltage of the opposite polarity at the extraction electrode(s) 104 will pull the ions out of the ion source as an ion beam. The extraction electrode(s) 104 may include one or more electrodes to accelerate the ion beam, decelerate the ion beam, shape the beam, aim the beam, etc. By providing an electric field that accelerates the ion beam out of the ion source 102, the extraction electrode(s) 104 provide the ion beam with an extraction energy of the same or similar magnitude as a voltage of the extraction electrode(s) 104. For example, an electrode at a voltage of 55 kV can provide the ion beam with an extraction energy of 55 kV (noting that ion kinetic energy is often expressed in volts in this context, with one volt equaling one joule per coulomb) as the ion beam pass the extraction electrode(s) 104.

An ion beam having a high extraction energy is thus provided as an output of the extraction electrode(s) 104. In various embodiments, the high extraction energy can be in a range between 20 kV and 80 kV, for example between 40 kV and 60 kV (e.g., 55 kV). In such embodiments, the voltage applied at the extraction electrode(s) 104 can be selected to provide the ion beam with the desired extraction energy for a particular scenario.

In the example of FIG. 1, the ion beam passes from the extraction electrodes 104 to the magnetic analyzer 106. In other embodiments, the magnetic analyzer 106 is omitted. The magnetic analyzer 106 is configured to provide a magnetic field that creates magnetic forces on the ion beam. The magnetic force on each ion may be approximately equal, but the ion beam may include ions of different isotopes, such that the masses of the ions vary. The magnetic force provided by the magnetic analyzer 106 may result in a separation of ions by mass. Thus, after passing through the magnetic analyzer 106, different areas of a transverse cross-section of the ion beam may include different isotopes, i.e., ions of different mass.

In FIG. 1, the ion beam is illustrated to pass from the magnetic analyzer 106 to the mass-resolving aperture 108, and the mass-resolving aperture 108 is configured to block an undesired subset of the ions from passing through the mass-resolving aperture 108, while allowing desired ions to pass through the mass-resolving aperture 108. In particular, ions allowed through the mass-resolving aperture 108 are primarily ions of a desired isotope (or two desired isotopes), while ions of one or more other isotopes are intercepted by the mass-resolving aperture 108. This is achieved by positioning the mass-resolving aperture 108 relative to the magnetic analyzer 106 to take advantage of the separation of isotopes by mass achieved by the magnetic analyzer 106. Various geometric arrangements are possible in various embodiments. Thus, in examples including the magnetic analyzer 106 and the mass-resolving aperture 108, the ion beam that reaches the target 110 includes a high percentage of a desired isotope or desired isotopes, with a low percentage of contamination by ions of different isotopes.

The ion beam from the mass-resolving aperture 108 is incident on target 110. The target 110 is configured to receive and collect the ions of the ion beam. The target 110 can include a substrate material suitable for receiving and retaining the ions, including as a film on a surface of the target 110 and/or embedded in a lattice structure of the target 110. For example, the substrate material of the target 110 may have a crystal structure. As another example, the substrate material of the target 110 may include a carbon fiber material (e.g., a carbon fiber cloth). The material(s) of the target 110 are also selected such that the target 110 is capable of being held at a substantially-constant voltage as ions are collected on, implanted in, or other received at the target 110. The material(s) of the target 110 may be selected to help cause sticking of the ions to or in the target 110. The target 110 may be removable and replaceable in the ion production system 100 to facilitate harvesting of the ionic material that builds up on the target 110 during operation of the ion source 102.

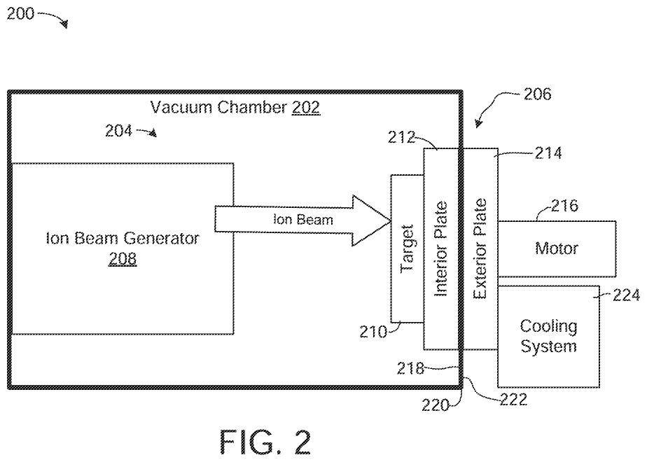

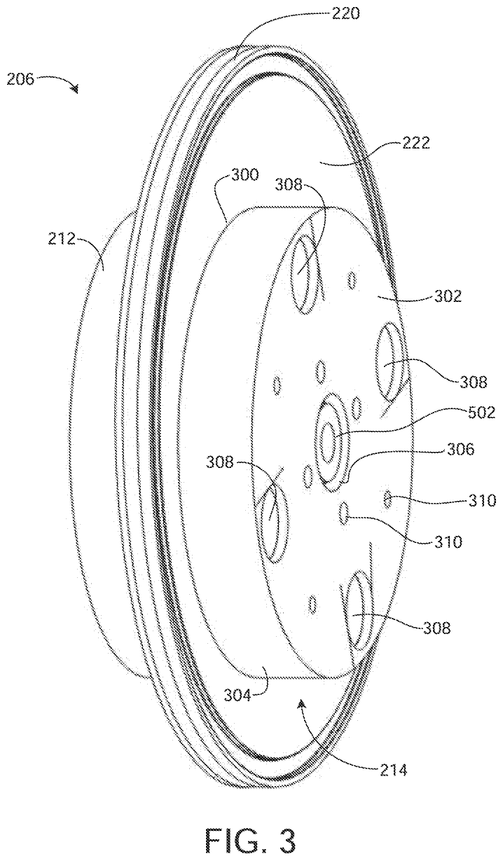

The target 110 is shown as being coupled to a voltage source 112, which is connected between the target 110 and ground 114. Other elements of the ion production system 100 also include suitable electronics elements, power sources, etc. to enable operation thereof. The voltage source 112 is configured to hold (put, establish, maintain, etc.) the target 110 at a voltage (referred to herein as the target voltage) which has the same polarity of the ion beam. For example, as illustrated in FIGS. 2-3 and discussed below, a positive voltage is provided to the target 110 by the voltage source 112 in scenarios where positive ions are generated by the ion source, while a negative voltage is provided to the target 110 by the voltage source 112 in scenarios where negative ions are generated by the ion source.

The target voltage is preferably less than the extraction energy of the ion beam, such that the ion beam is able to reach the target without being forced in the opposite direction by the target voltage, while being high enough to reduce the energy of ion beam far enough to minimize both electronic and nuclear stopping of the ion beam at the target 110 (thereby minimizing scattering or sputtering that would otherwise be caused by high-energy collisions between the ions and the target 110). For example, the target voltage may be less than the extraction energy by an amount corresponding to a thermal energy of the ions, such that the energy of the ions is reduced to thermal energy just as the ions reach the target 110. In various embodiments, the target voltage is both less than the extraction energy and greater than 95% of the extraction energy, for example greater than 99% of the extraction energy (while also being less than the extraction energy). In some examples, the target voltage is approximately 100 V less than the extraction energy such that the ion beam has an energy of approximately 100 V when the ion beam reaches the target (e.g., extraction energy minus target voltage equals approximately 100V). In one example, the extraction energy is 55 kV and the target voltage is 54.9 kV.

In some embodiments, the voltage source 112 and the target 110 are configured so that the voltage of the target 110 stays substantially constant throughout operation of the ion production system 100 and as ions collect on the target 110 (e.g., as a film on the target 110, embedded in the target 110) and are constituted into a neutral material (e.g., of the desired isotope(s)). In some cases, to facilitate removal of the constituted ionized material from the target 110, the target 110 can be removable from the ion production system 100. In some such cases, the voltage source 112 is controlled to gradually reduce the target voltage toward zero to enable the target 110 to be disconnected from the voltage source 112 without disrupting the ionized material collected thereon. In some embodiments, the target 110 (or a portion thereof) is removed for use in transport and further processing of the ionized material, and replaced with a new target 110 (or new portion thereof) for use in subsequent operation of the ion production system 100. In other embodiments, the ionized material can be removed from the target 110 and collected in a receptacle (or other collection and retention device) such that the target 110 can be reused in a subsequent operation of the ion production system 100 to collect more ions.

Referring now to FIG. 2, a schematic diagram of an apparatus 200 that includes a vacuum chamber 202, an ion production system 204, and magnetic rotation device 206 is shown, according to some embodiments.

The ion production system 204 is shown as including an ion beam generator 208 and a target 210. The ion beam generator 208 is configured to generate an ion beam and direct the ion beam toward the target 210 so that the ion beam is incident on the target 210. The ion beam generator 208 can include the ion source 102, the extraction electrodes 104, the magnetic analyzer 106, and/or the mass-resolving aperture 108 of FIG. 1, for example. The target 210 may be configured the same as the target 110 of FIG. 1, for example.

As shown in FIG. 2, the target 210 is coupled to the magnetic rotation device 206. The magnetic rotation device 206 includes an interior plate (first plate) 212, and exterior plate (second plate) 214, and a motor 216. The interior plate 212 is inside (interior to, internal to, contained in) the vacuum chamber 202 and is positioned on an interior side 218 of a wall 220 of the vacuum chamber 202. The exterior plate 214 is outside (exterior to, external to, not contained in) the vacuum chamber 202 and is positioned on an exterior side 222 of the wall 220. The motor 216 is mechanically coupled to the exterior plate 214. The target 210 is mechanically coupled to the interior plate 212.

The motor 216 is operable to drive rotation of the exterior plate 214. The motor 216 may be an electric motor, for example a stepper motor, which transforms electricity into rotational movement. The motor 216 is coupled to the exterior plate 214 such that operation of the motor 216 exerts a torque on the exterior plate 214 that causes rotation of the exterior plate 214 about an axis of the exterior plate 214. A rotating drive shaft of the motor 216 can be aligned with the axis of the exterior plate 214 to directly transfer the torque to the exterior plate 214 to cause rotation of the exterior plate 214. The motor 216 can be controllable to rotate the exterior plate 214 at various speeds. In some embodiments, the motor 216 is operated to rotate the exterior plate 214 at a pace of approximately one rotation per minute.

The exterior plate 214 includes one or more magnets (e.g., permanent magnets) and the interior plate 212 also includes one or more magnets (e.g., permanent magnets) corresponding to the one or more magnets of the exterior plate 214. An example arrangement of magnets in the interior plate 212 and the exterior plate 214 is shown in FIGS. 3-6 and described with reference thereto. The magnets of the exterior plate 214 and the interior plate 212 are arranged such that an attractive force is exerted on the interior plate 212 by the exterior plate 214 and vice versa. For example, the one or more magnets of the exterior plate 214 may be arranged with a positive magnetic polarity facing the wall 220 while the one or more magnets of the interior plate 212 are arranged with a negative magnetic polarity facing the wall 220 (or vice versa), such that the magnets are attracted toward one another and a magnetic force pulls the interior plate 212 and the exterior plate 214 together. The magnets provide sufficiently strong magnetic fields to exert the attractive force across the wall 220 of the vacuum chamber 202. The wall 220 may be approximately half of an inch thick in some embodiments.

Due to the attractive magnetic force between the magnets of the exterior plate 214 and the interior plate 212, rotation of the exterior plate 214 by the motor 216 causes rotation of the interior plate 212. In the examples shown, the interior plate 212 rotates to match the rotation of the exterior plate 214 due to magnetic coupling therebetween. Rotational movement and torque (e.g., angular kinetic energy) is thereby communicated across the wall 220 of the vacuum chamber 202 without compromising the integrity of a hermetic seal of the vacuum chamber 202 (e.g., without requiring mechanical engagement between the interior plate 212 and the exterior plate 214 that may be difficult to hermetically seal). Because, as shown in FIG. 2, the target 210 is mounted on the interior plate 212, rotation of the interior plate 212 rotates the target 210. Although the examples herein refer to rotation, in other embodiments the motor 216 is arranged to translate the exterior plate 214 (e.g., in one or two dimensions) to thereby cause corresponding translation of the interior plate 212 and the target 210. Operation of the motor 216 thereby causes motion of the target 210, for example rotation of the target 210.

As illustrated in FIG. 2, the ion beam generator 208 directs the ion beam at the target 210 so that the ion beam is misaligned (offset, etc.) relative to an axis of rotation of the target 210. Accordingly, when the target 210 rotates by operation of the magnetic rotation device 206, the point or area at which the ion beam is incident on the target 210 changes. Rotation of the target 210 over time causes the ion beam to be incident on different portions of the target 210 over time, thereby increasing a total area of the target 210 that is exposed to the ion beam. Movement of the target 210 thereby allows a larger area of the target 210 to be exposed to the ion beam and to capture ions and/or isotopes from the ion beam. The target 210 can thus capture more material as compared to an embodiment with a static target 210, allowing for longer continuous operation of the apparatus 200 before the target is full (saturated, at capacity, etc.). Rotating the target can also help reduce temperature gradients across the target, which may be undesirable.

The magnetic rotation device 206 is also configured to provide heat transfer into or out of the vacuum chamber, for example to remove heat from the target 210 to manage the temperature thereof. As shown, the interior plate 212 and the exterior plate 214 are both positioned in contact with the wall 220 of the vacuum chamber 202. The interior plate 212 and the exterior plate 214 can include a material with high thermal conductivity (e.g., low resistance to heat flow therethrough), for example a metal such as steel. The wall 220 may be made of a similar material. The interior plate 212 and the exterior plate 214 are in thermal contact with one another via the wall 220. Such thermal contact is maintained by the attractive force between the magnets of the interior plate 212 and the exterior plate 214 which can force the interior plate 212 and the exterior plate 214 towards one another and into contact with the wall 220. The target 210 shown as positioned on the interior plate 212. A pathway for heat transfer is thereby provided from the target 210 to the exterior plate 214.

In the embodiment shown, the apparatus 200 also includes a cooling system 224 in thermal communication with the exterior plate 214. The cooling system 224 can include a refrigeration cycle (including a compressor, condenser, expansion valve, and evaporator, for example) configured to remove heat from the exterior plate 214. For example, the cooling system 224 may provide a chilled fluid through one or more coils or other heat exchanger in thermal contact with the exterior plate 214. Cooling of the exterior plate 214 increases the heat flow away from the target 210, which may be desirable in embodiments where collision of the ion beam with the target 210 provides thermal energy to the target 210. In other scenarios (e.g., other use cases for the magnetic rotation device 206), the cooling system 224 can include or be replaced with a heating system configured to provide thermal energy to the exterior plate 214 in order to transfer thermal energy (heat) into the vacuum chamber 202 via the interior plate 212.

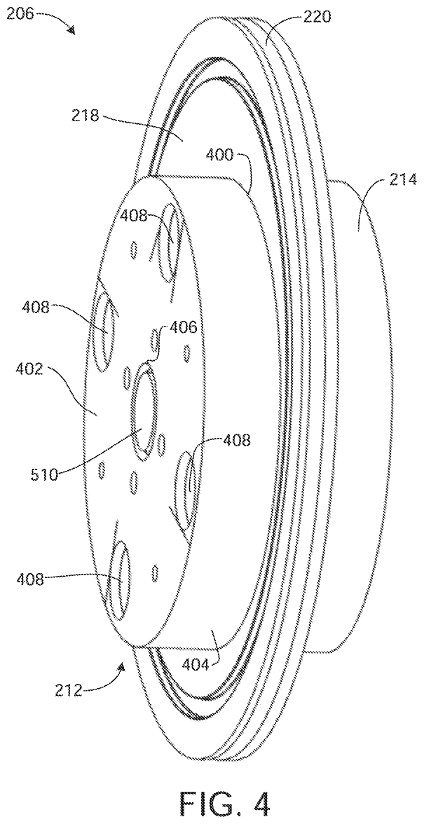

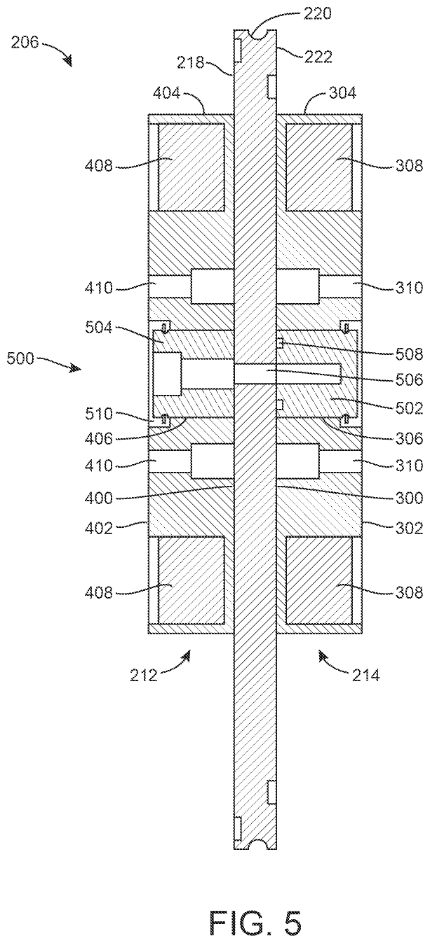

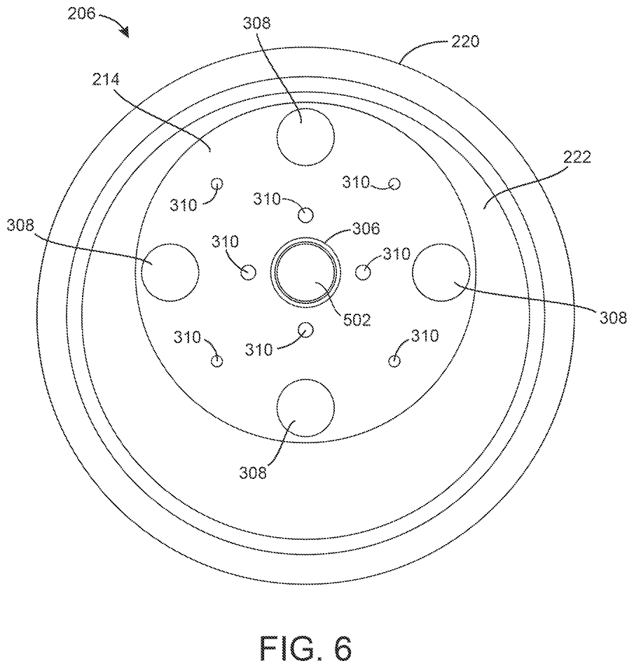

Referring now to FIGS. 3-6, multiple views of the magnetic rotation device 206 are shown, according to some embodiments. Other designs for a magnetic rotation device are also within the scope of the present disclosure. FIG. 3 shows an isometric view primarily showing the exterior plate 214, FIG. 4 shows an isometric view primarily showing the interior plate 212, FIG. 5 shows a cross-section side view, and a FIG. 6 shows a front view of the exterior plate 214. Reference is made to FIGS. 3-6 in the following description. FIGS. 3-6 show the magnetic rotation device 206 as installed on the wall 220 of the vacuum chamber 202.

The exterior plate 214 is shown as a disc having a round shape, in particular a circular shape. The exterior plate 214 may be another shape in other embodiments (e.g., polygonal, non-polygonal, rectangular, square, pentagonal, hexagonal, heptagonal, octagonal, etc.). The exterior plate 214 has a first flat surface 300 that mates against the exterior side 222 of the wall 220 in the example shown, a second flat surface 302 opposite the first flat surface 300, and a circumferential surface 304 extending from the first flat surface 300 to the second flat surface 302. A dry lubricant, for example a fluoropolymer, can be positioned on the first flat surface 300 and/or the exterior side 222 of the wall 220 to reduce sliding friction therebetween and facilitate rotation of the exterior plate 214 along the wall 220.

The exterior plate 214 is shown as including a hub 306 at a center axis of the exterior plate 214. The hub 306 is shown as a cylindrical opening that defines an axis of rotation of the exterior plate 214.

The hub 306 is configured to receive an axel 500 (as best shown in FIG. 5), in particular an exterior end 502 of the axel 500 which extends away from the exterior side 222 of the wall 220. The axel 500 also includes an interior end 504 opposite the exterior end 502, i.e., extending from the interior side 218 of the wall 220 into the vacuum chamber 202. In the example shown, the exterior end 502 of the axel 500 has a radius that matches a size of the cylindrical opening of the hub 306, while a narrower connecting section 506 of the axel 500 extends through a hole in the wall 220 to the interior end 504 of the axel 500. In other embodiments, the exterior end 502 and the interior end 504 are formed directly on the wall 220 without a connecting section 506 extending through the wall 220. An o-ring 508 is provided between the exterior end 502 of the axel 500 and the exterior side 222 of the wall 220 and hermetically seals the exterior end 502 to the exterior side 222 of the wall 220 to prevent any pressure leaks at the axel 500.

The hub 306 is configured to turn (rotate, spin, etc.) on the axel 500, with the axel 500 remaining stationary in the embodiment shown. The hub 306 can be selectively slid on and off of the axel, for example during assembly or disassembly of the magnetic rotation device 206. Magnetic forces as described below are sufficient to retain the exterior plate 214 on the axel 500 absent an external force on the exterior plate 214 (e.g., a force from a technician pulling the exterior plate 214 away from the wall 220). In some embodiments, a snap-on plate or other retention feature can be engaged with the hub 306 and the exterior end 502 of the axel 500 to retain the hub 306 and the exterior plate 314 on the hub 306.

The exterior plate 214 also includes multiple magnets, shown as four magnets 308. The magnets 308 may be permanent magnets with stable magnetic polarity, such that each magnet 308 provides a substantially static magnetic field when stationary. The four magnets 308 may be oriented in a common direction, such that the polarities thereof are aligned. For example, the four magnets 308 may all be aligned with a positive polarity directed toward the wall 220. As another example, the four magnets 308 are all aligned with a negative polarity directed toward the wall 220. Although the example shows four magnets 308, any number of magnets can be used in various embodiments (e.g., one, two, three, four, five, six, seven, eight, etc.).

The magnets 308 are positioned in recesses (openings, slots, receptacles, etc.) in the second flat surface 302 of the exterior plate 214 such that the magnets 308 are positioned proximate the first flat surface 300 such that the magnets 308 provide a magnetic field which crosses the first flat surface 300. The magnets 308 can be mechanically retained in the recesses (e.g., coupled to other structures of the exterior plate 214 with a clip, bolt, etc., threaded into the recesses, high friction between the magnets 308 and the recesses, adhered to the recesses, etc.) and/or may be held in the recesses by magnetic forces acting thereon. In the example of FIGS. 3-6, the magnets 308 are cylindrical.

The magnets 308 are equidistant from the hub 306 and from an axis of rotation of the exterior plate 214 (e.g., from a center of the axel 500). For example, the magnets 308 may all be a given radius away from the axis of rotation of the exterior plate 214. Due to this arrangement, when the exterior plate 214 rotates, the magnets 308 move along a common path, in particular along the same circle having a radius defined by the spacing of the magnets 308 from the axis of rotation of the exterior plate 214. As shown, the magnets 308 are spaced at equal intervals around such a circle or path. This provides ease of alignment with the interior plate 212 as discussed below and facilitates recovery from jams, skips, slips, etc. during operation of the magnetic rotation device 206.

As shown, the magnets 308 are positioned proximate the circumferential surface 304 of the second flat surface 302, i.e., near a perimeter of the exterior plate 214. When greater distance is provided between the magnets 308 and the axel 500, the load on each magnet 308 created during rotation of the exterior plate 214 to rotate the interior plate 212 is reduced. Placing the magnets 308 around a circumference of a disc (i.e., near the circumferential surface 304 of the exterior plate 212) can thus allow less or weaker magnets to be used as compared to another embodiment where the magnets are positioned closer to the axel 500.

The exterior plate 214 is also shown as including bolt holes 310. The bolt holes 310 are arranged in various positions on the exterior plate 214 and are configured to provide for attachment of other components, devices, equipment, etc. to the exterior plate 214. For example, the motor 216 can be coupled to the exterior plate 214 by using bolts (screws, etc.) to couple a rotating drive shaft of the motor 216 to at least a subset of the bolt holes 310. The motor 216 can then transfer torque to the exterior plate 214 via the bolt holes 310. The bolt holes 310 may be threaded to allow a threaded bolt to be securely connected thereto.

The interior plate 212 is shown as being configured substantially the same as the exterior plate 214, which may facilitate manufacturing and enable easy and reliable alignment between the interior plate 212 and the exterior plate 214, but distinct compatible designs may be used in other embodiments. The interior plate 212 is shown as a disc having a round shape, in particular a circular shape. The interior plate 212 may be another shape in other embodiments (e.g., polygonal, non-polygonal, rectangular, square, pentagonal, hexagonal, heptagonal, octagonal, etc.). The interior plate 212 has a first flat surface 400 that mates against the interior side 218 of the wall 220 in the example shown, a second flat surface 402 opposite the first flat surface 400, and a circumferential surface 404 extending from the first flat surface 400 to the second flat surface. A dry lubricant, for example a fluoropolymer, can be positioned on the first flat surface 400 and/or the interior side 218 of the wall to reduce sliding friction therebetween and facilitate rotation of the interior plate 212 along the wall 220. Other types of lubricants (e.g., oil-based lubricants) may not be suitable for use in high vacuum inside the vacuum chamber 202). In the example shown, the shape of the interior plate 212 matches the shape of the exterior plate 214. As shown, the interior plate 212 is aligned with the exterior plate 214 across the wall 220.

The interior plate 212 has a hub 406 at a center axis of the interior plate 212. The hub 406 is shown as a cylindrical opening that defines an axis of rotation of the interior plate 212. The hub 406 receives the axel 500, in particular the interior end 504 of the axel 500 that extends from the interior side 218 of the wall 220. The hub 406 is configured to turn (rotate, spin, etc.) on the axel 500, with the axel 500 remaining stationary in the embodiment shown. In the example, shown a snap-on plate (snap ring, retention member, etc.) 510 is included and engages both a notch or groove of the axel 500 and a lip or step of the hub 406 such that the snap-on plate 510 is retained on the axel 500 and prevents the hub 406 from sliding off of the axel 500. The hub 406 is thereby retained on the axel 500. In some embodiments, the snap-on plate 510 is omitted while magnetic attractive forces between the interior plate 212 and the exterior plate 214 act to retain the hub 406 on the axel 500.

The interior plate 212 includes multiple magnets, shown as four magnets 408. Although the example shows four magnets 308, any number of magnets can be used in various embodiments (e.g., one, two, three, four, five, six, seven, eight, etc.). The magnets 408 may be permanent magnets with stable magnetic polarity, such that each magnet 308 provides a substantially static magnetic field when stationary. The four magnets 408 may be oriented in a common direction, such that the polarities thereof are aligned, and in particular such that the polarities thereof point in an opposite direction than the polarities of the magnets 308 of the exterior plate 214. If the magnets 308 of the exterior plate 214 are oriented with a positive polarity directed toward the wall 220, the magnets 408 of the interior plate 212 are oriented with a negative polarity directed toward the wall 220. If the magnets 308 of the exterior plate 214 are oriented with a negative polarity directed toward the wall 220, the magnets 408 of the interior plate 212 are oriented with a positive polarity directed toward the wall 220. As such, the magnetic fields of the magnets 308 of the exterior plate 214 and the magnets 408 of the interior plate will interact to create an attractive magnetic force that pulls the interior plate 212 toward the exterior plate 214 and vice versa.

The magnets 408 are positioned in recesses (openings, slots, receptacles, etc.) in the second flat surface 402 of the interior plate 212 such that the magnets 408 are positioned proximate the first flat surface 400 such that the magnets 408 provide a magnetic field which crosses the first flat surface 400. The magnets 408 can be mechanically retained in the recesses (e.g., coupled to other structures of the interior plate 212 with a clip, bolt, screen, etc., threaded into the recesses, high friction between the magnets 408 and the recesses, adhered to the recesses, etc.) and/or may be held in the recesses by magnetic forces acting thereon. In the example of FIGS. 3-6, the magnets 408 are cylindrical.

The magnets 408 of the interior plate 212 (interior magnets 408) are arranged to align with the magnets 308 of the exterior plate 214 (exterior magnets 308). A spacing (distance, radius, etc.) of the interior magnets 408 from the hub 406 and the axel 500 matches the spacing of the exterior magnets 308 from the hub 306 and the axel 500, such that the interior magnets 408 are arranged along the same path as the exterior magnets 308. Additionally, the interior magnets 408 are spaced at equal intervals around said path, matching the layout of the exterior magnets 308.

When the interior plate 212 and the exterior plate 214 are both installed on the axel 500 and at the wall 220 as shown in FIGS. 3-6, each of the interior magnets 408 aligns with one of the exterior magnets 308. Because of the symmetry in the arrangement/layout of the interior magnets 408 and the exterior magnets 308, there are multiple relative orientations that achieve such alignment. That is, the layout of the magnets 408, 308 is such that alignment of any one interior magnet 408 with any one exterior magnet 308 ensures alignment of the remaining interior magnets 408 with the remaining exterior magnets 308.

Once aligned, magnetic attractive forces between the interior magnets 408 and the exterior magnets 308 act to maintain the alignment, such that movement of the exterior magnets 308 causes movement of the interior magnets 408. Rotation of the exterior plate 214 (e.g., manually, by operation of the motor 216, etc.) causes movement of the exterior magnets 308 along a circular path, which magnetically forces movement of the interior magnets 408 along the same circular path, thereby causing rotation of the interior plate 212. The matching layout of the interior magnets 408 and the exterior magnets 308 also ensures that, if the magnetic connection and alignment therebetween is temporarily lost during rotation of the exterior plate 214 (e.g., due to a jam, resistance, inertia, etc.), the exterior magnets 308 will eventually realign with the interior magnets 408 by continuing to rotate along the shared path. The interior magnets 408 and the exterior magnets 308 are thus arranged to provide for reliable and self-repairing transfer of rotary motion across the wall 220.

The interior plate 212 is also shown as including bolt holes 410. The bolt holes 410 are arranged in various positions on the interior plate 212 and are configured to provide for attachment of other components, devices, equipment, etc. to the interior plate 212. For example, the target 210 can be coupled to the interior plate 212 by using bolts (screws, etc.) to couple the target 210 to at least a subset of the bolt holes 410. The interior plate 212 can then transfer torque and rotation to the target 210 via the bolt holes 410. The bolt holes 310 may be threaded to allow a threaded bolt to be securely connected thereto.

As shown in FIGS. 3-5, the attractive magnetic forces between the interior magnets 408 and the exterior magnets 408 pull the interior plate 212 and the exterior plate 214 into contact or close proximity with the wall 220. The interior plate 212, the wall 220, and the exterior plate 214 may be made of the same or similar thermally-conductive materials (e.g., metal, steel, etc.) such that, when magnetically held together as in FIGS. 3-5, provide a substantially continuous mass through which heat can flow, for example across the interior surface area of first flat surface 400 the interior plate 212 through the wall 220 to the entire surface area of the first flat surface 300 of the exterior plate 214. The close contact and large exposed surface area provides for highly efficient heat transfer across the magnetic rotation device 206.

The systems described herein can allow for the following operations, in various embodiments. An ion beam can be provided so that it is incident on the target 210 in the vacuum chamber 202. The target 210 can be rotated by driving rotation of the exterior plate 214 outside the vacuum chamber 202, for example using the motor 216 (e.g., stepper motor) coupled to the exterior plate 214 and also positioned outside the vacuum chamber 202. Magnets 308 of the exterior plate 214 exert an attractive magnetic force on magnets 308 of the interior plate 212 inside the vacuum chamber 202 that transfer the rotation of the exterior plate 214 to the interior plate 212, thereby transferring rotation across a wall 220 of the vacuum chamber 202. The target 210 can be mounted on the interior plate 212 so that the rotation of the interior plate 212 causes rotation of the target 210. Rotating the target 210 can increase an area of the target exposed to the ion beam due to misalignment of the ion beam relative to an axis of rotation of the target. Heat can be transferred from the target 210 via the interior plate 212 to the exterior plate 214 via the wall 220, for example to cool the target 210. Operating the systems herein can also include operating a refrigeration cycle (e.g., of cooling system 224) that cools the exterior plate 214. These and other processes are enabled by the systems and methods described herein.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical values or idealized geometric forms provided. Accordingly, these terms should be interpreted as indicating that insubstantial or inconsequential modifications or alterations of the subject matter described and claimed are considered to be within the scope of the disclosure as recited in the appended claims.

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure. References to elements as “first,” “second,” “additional,” etc. are used as non-descriptive labels for the sake of differentiating components, can be used in place of other labels or names used herein, and should be considered fully supported by the present disclosure. For example, the terms “first plate” and “second plate” should be understood as being supported in a non-limiting manner by disclosure relating to the interior plate and exterior plate above.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

What is claimed is:

1. An apparatus, comprising:
a wall defining a boundary of an evacuated space and comprising a first side interior to the evacuated space and a second side exterior to the evacuated space;
a first plate positioned on a first side of the wall and comprising a first magnet;
a second plate positioned on a second side of the wall and comprising a second magnet; and
a motor mechanically coupled to the second plate and configured to drive rotation of the second plate;
wherein the second magnet exerts an attractive force on the first magnet that causes rotation of the first plate in response to the rotation of the second plate.

2. The apparatus of claim 1, wherein the attractive force enables heat transfer from the first plate to the second plate by drawing the first plate into thermal contact with the wall and the second plate into thermal contact with the wall.

3. The apparatus of claim 1, further comprising a cooling coil in thermal contact with the second plate.

4. The apparatus of claim 1, further comprising an axle coupled to the wall and having a first end on the first side of the wall and a second end on the second side of the wall;
wherein the first plate rides on the first end of the axle; and
wherein the second plate rides on the second end of the axle.

5. The apparatus of claim 4, wherein the attractive force holds the second plate on the axle.

6. The apparatus of claim 4, further comprising an o-ring positioned around the axle at the wall, wherein the axle and the o-ring are stationary relative to the wall during the rotation of the first plate and the second plate.

7. The apparatus of claim 1, wherein the first plate and the second plate have a same size and a same shape.

8. The apparatus of claim 1, wherein the same shape is a circular shape.

9. The apparatus of claim 1, wherein:
the first plate further comprises a plurality of additional first magnets and the second plate further comprises a plurality of additional second magnets;
the first magnet and the plurality of additional first magnets are spaced apart from each other and positioned a distance away from an axis of the rotation of the first plate; and
the second magnet and the plurality of additional second magnets are spaced apart from each other and positioned the distance away from an axis of the rotation of the second plate.

10. The apparatus of claim 1, wherein the first plate slides along the first side of the wall during the rotation of first plate and the second plate slides along the second side of the wall during the rotation of the second plate.

11. The apparatus of claim 9, further comprising a fluoropolymer dry lube positioned between the first plate and the first side of the wall to reduce friction therebetween.

12. The apparatus of claim 1, further comprising a target mounted on the first plate, the target configured to trap particles from an ion beam incident thereon.

13. The apparatus of claim 12, wherein the rotation of the first plate changes an area of the target exposed to the ion beam.

14. The apparatus of claim 12, further comprising an ion beam generator configured to generate the ion beam inside the evacuated space and direct the ion beam toward the target.

15. The apparatus of claim 1, wherein the apparatus is an ion production system.

16. A method, comprising:
providing an ion beam incident on a target in a vacuum chamber;
rotating the target by:
driving rotation of an exterior plate outside the vacuum chamber, the exterior plate comprising an exterior magnet; and
transferring the rotation of the exterior plate to an interior plate inside the vacuum chamber via an attractive force between the exterior magnet and an interior magnet of the interior plate, wherein the target is mounted on the interior plate.

17. The method of claim 16, further comprising transferring heat from the target to the exterior plate via the interior plate and a wall of the vacuum chamber.

18. The method of claim 17, further comprising operating a refrigeration cycle that cools the exterior plate.

19. The method of claim 16, wherein driving the rotation of the exterior plate comprises operating a stepper motor coupled to the exterior plate.

20. The method of claim 17, wherein rotating the target increases an area of the target exposed to the ion beam due to misalignment of the ion beam relative to an axis of rotation of the target.
